(19) United States
(12) Patent Application Publication
(10) Pub. No.: US 2005/0203269 A1
(43) Pub. Date: Sep. 15, 2005

(54) Dicarboxylic acids for dielectrics having barrier effect against copper diffusion

(76) Inventors: Andreas Walter, Egloffstein (DE); Recai Sezi, Roettenbach (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/016,900

(22) Filed: Dec. 21, 2004

Related U.S. Application Data
(63) Continuation of application No. PCT/DE03/01752, filed on May 30, 2003.

(30) Foreign Application Priority Data
Jun. 27, 2002 (DE) 102 28 762.7

(51) Int. Cl. C08G 63/02; H01L 21/44

(52) U.S. Cl. 528/272

(57) ABSTRACT

Novel dicarboxylic acids are described herein that are suitable for the preparation of high-temperature-stable polymers, which are particularly useful in forming suitable dielectrics in microelectronics.

### CROSS REFERENCE TO RELATED APPLICATIONS

This application is a continuation of PCT/DE03/001752, filed May 30, 2003, and titled “Dicarboxylic Acids for Dielectrics Having Barrier Effect Against Copper Diffusion,” which claims priority under 35 U.S.C. §119 to German Application No. DE 102 28 762.7, filed on Jun. 27, 2002, and titled “Dicarboxylic Acids for Dielectrics Having Barrier Effect Against Copper Diffusion,” the entire contents of which are hereby incorporated by reference.

### FIELD OF THE INVENTION

The invention relates to dihydroxyl compounds and to a process for their preparation. Such dihydroxyl compounds are suitable for the preparation of poly-o-hydroxyamides which can be used after conversion to the corresponding polybenzoxazoles as a dielectric in microchips.

### BACKGROUND

In order to prevent crosstalk, caused by capacitive coupling of signals, adjacent conductor tracks in microchips are insulated from each other by a dielectric disposed between the conductor tracks. Compounds which are to be used as dielectrics have to satisfy various demands. For instance, the signal propagation time in microchips depends both on the material of the conductor track and on the dielectric which is disposed between the conductor tracks. The lower the dielectric constant of the dielectric, the shorter the signal propagation time. The silicon dioxide-based dielectrics used hitherto have a dielectric constant of approx. 4. These materials are gradually being replaced by organic dielectrics which have a distinctly lower dielectric constant. The dielectric constant of these materials is usually below 3.

In the microchips used currently, the conductor tracks consist preferably of aluminum, AlCu or AlCuSi. With increasing integration density of the memory chips, there is a transition to copper as the conductor track material owing to its lower electrical resistance in comparison to aluminum. Copper allows shorter signal propagation times and thus a reduction in the conductor track cross section. Unlike the techniques customary hitherto, in which the dielectric is introduced into the trenches between the conductor tracks, the dielectric is structured first in the copper damascene technique. The resulting trenches and contact holes are first coated with a thin barrier which consists, for example, of titanium, titanium nitride, silicon carbide, silicon nitride or silicon carbonitride. Subsequently, the trenches are initially filled with copper and then excess copper is ground off mechanically. The dielectric therefore has to be stable toward the materials used for grinding and has sufficient adhesion to the substrate, in order not to be removed during the mechanical grinding process. In addition, the dielectric has to have a sufficient stability in the downstream process steps, in which further components of the microchips are generated. To this end, the dielectric has to have, for example, a sufficient thermal stability and must not undergo any decomposition even at temperatures of more than 400° C. In addition, the dielectric has to be stable toward process chemicals such as solvents, strippers, bases, acids or aggressive gases. Further requirements are a good solubility and sufficient storage stability of the precursors, from which the dielectric is obtained.

Polybenzoxazoles (PBOs) are polymers which have a very high heat resistance. These substances are already being used to prepare protective and insulating layers in microchips. Polybenzoxazoles may be prepared from poly-o-hydroxyamides by cyclization. The poly-o-hydroxyamides exhibit a good solubility in organic solvents and good film-forming properties. They can be applied by means of spincoating techniques in a simple manner to electronic components. After a thermal treatment in which the poly-o-hydroxyamide is cyclized to the polybenzoxazole, a polymer is obtained which has the desired properties. Polybenzoxazoles can be processed directly in their cyclized form. However, there are generally difficulties in this case with the solubility of the polymer. Building blocks for poly-o-hydroxyamides are described, for example, in DE 100 11 608, the disclosure of which is incorporated herein by reference in its entirety.

The mechanism which proceeds in the cyclization of poly-o-hydroxyamides to polybenzoxazoles is shown schematically below:

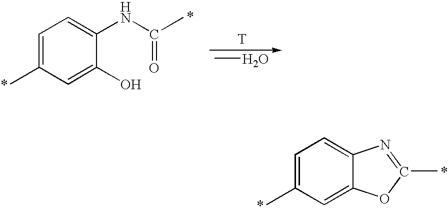

In the course of heating, the o-hydroxyamide cyclizes to the oxazole, and water is released.

In the production of microchips, manufacturing stages are passed through which cause thermal stresses of up to 400° C., for example oxide deposition, copper annealing or tungsten deposition from the gas phase. In these manufacturing steps, the metal must not diffuse out of the conductor tracks into the dielectric surrounding them. A barrier is therefore provided between dielectric and metal, which effectively suppresses a diffusion of the metal atoms. Suitable materials have already been mentioned above. The barrier functions neither as a good dielectric nor as a good conductor. In order to suppress diffusion of the metal atoms, the barrier has to have a certain layer thickness. With decreasing size of the components, the relative proportion of the barrier in the space available for a conductor track therefore increases, so that the integration density reaches a limit. At a conductor width of 100 nm and less, the barrier can occupy up to 10% of the width available. For a further miniaturization of the components, it is therefore necessary to reduce the space requirement of the barrier or, in the ideal case, to be able to dispense with a barrier. This would also enable a cost saving, since a deposition of the barrier becomes unnecessary.

Dicarboxylic acids are required in particular as starting materials for the preparation of high-temperature-stable polymers, for example polybenzoxazoles and precursors thereof, and also for the preparation of polyimides and precursors thereof (polyamidocarboxylic acids). Such reactions are described, for example, in EP 264 678 or EP 023 662, the disclosures of which are incorporated herein by reference in their entireties. For the preparation of the poly-o-hydroxyamides serving as a precursor for polybenzoxazoles, a dicarboxylic acid or activated derivative thereof, for example a dicarbonyl chloride, is reacted with a bisaminophenol. After the application to a semiconductor substrate, the polymeric precursor is cyclized thermally to polybenzoxazole and thus obtains the desired properties.

The properties of the polymer are influenced substantially by the type of the dicarboxylic acid used. Variation of the structure of the dicarboxylic acid allows not only the thermal, electrical or mechanical behavior, but also the solubility, hydrolysis stability, storability and numerous further properties of the polymer to be influenced. For polybenzoxazoles which are suitable as a dielectric between two metal planes, for example in multichip modules, memory and logic chips, or as a buffer layer between the chip and its casing, good electrical, chemical, mechanical and thermal properties are required. In order in particular to be able to satisfy the demands which result from the constantly decreasing dimensions of the semiconductor components in a microchip, it is necessary to constantly develop novel starting materials which can satisfy these rising demands.

A significant point is, for example, the suppression, already described above, of the diffusion of copper from the conductor tracks into the dielectric.

### SUMMARY OF THE INVENTION

It is therefore an object of the invention to provide novel dicarboxylic acids which enable the preparation of high-temperature-resistant polymers which are suitable as dielectrics for microchips.

The object is achieved in accordance with the invention by providing dicarboxylic acids of the following formula I: 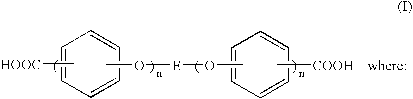
E is any of the following: 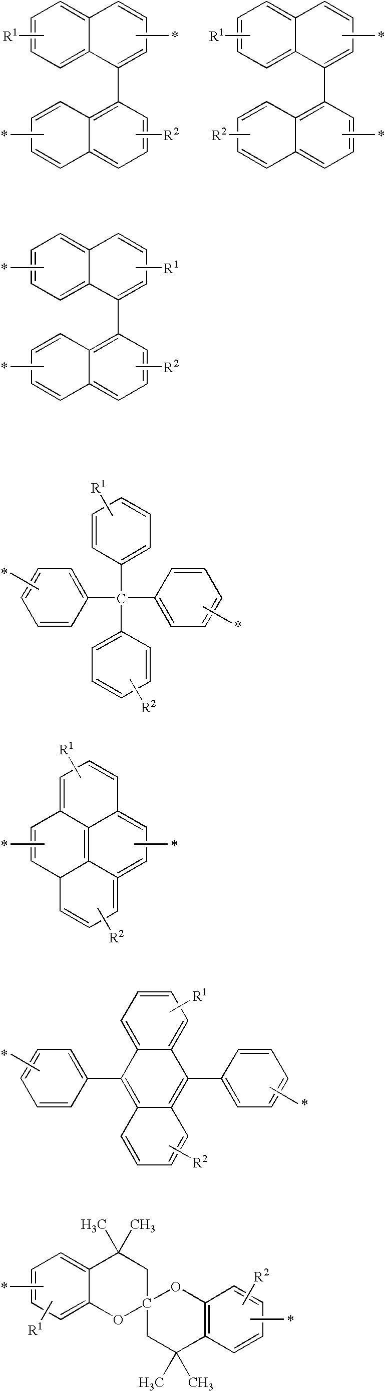 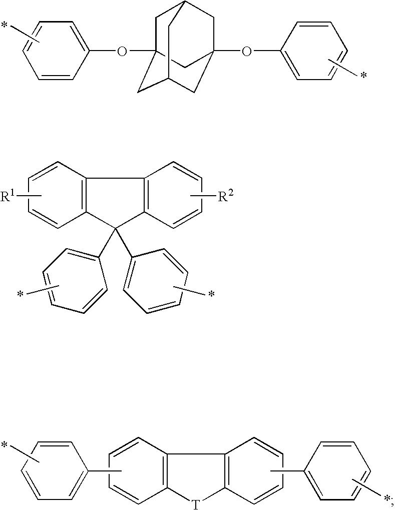
T is any of the following: 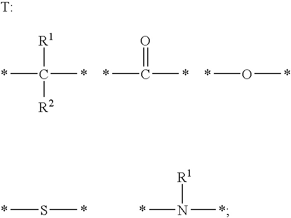
R¹, R² are independent of each other and each of R¹ and R² is any of the following: 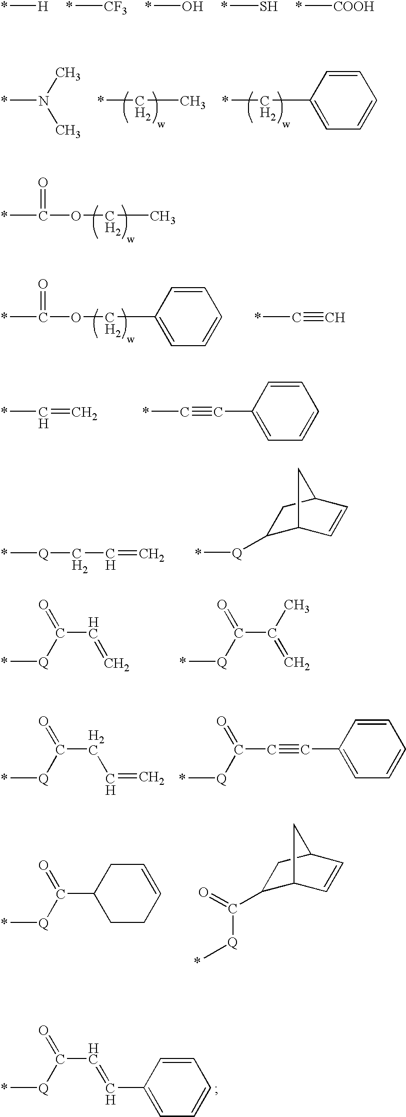
Q is independent for each of R¹ and R² and is any of the following: 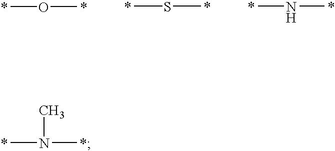
n is 0 or 1; and
w is an integer from 0 to 10.

The above and still further objects, features and advantages of the present invention will become apparent upon consideration of the following detailed description of specific embodiments thereof.

### DETAILED DESCRIPTION

As noted above, the invention includes providing dicarboxylic acids of the above formula I that enable the preparation of high-temperature-resistant polymers which are suitable as dielectrics for microchips.

The dicarboxylic acids of the above formula I enable the preparation of high-temperature-resistant polymers, especially polybenzoxazoles, which are notable in particular for a distinct suppression of the diffusion of copper. The poly-o-hydroxyamides prepared from the dicarboxylic acids of formula I are very soluble in many solvents and can be applied efficiently to semiconductor substrates by customary techniques, such as spincoating, spraying or dipping techniques, to obtain a very good quality of the film. Suitable solvents are, for example, acetone, cyclohexanone, diethylene glycol monoethyl ether or diethylene glycol diethyl ether, N-methylpyrrolidone, γ-butyrolactone, ethyl lactate, methoxypropyl acetate, tetrahydrofuran or ethyl acetate.

After the cyclization to the polybenzoxazole, the polymers have a high stability even at temperatures of more than 400° C. and are stable toward acids, bases and solvents. The polybenzoxazoles prepared from the dicarboxylic acids of formula I substantially suppress the diffusion of the copper from the conductor tracks in to the dielectric, so that the barriers which are typically required can be very thin, or the barriers can be dispensed with altogether.

In a preferred embodiment, the dicarboxylic acids of formula I include phenylenoxy groups. In this case, n=1, and the dicarboxylic acids preferably have a structure shown in the following formula II: 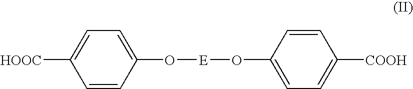
where E is as defined above in formula I. These compounds can be prepared in isomerically pure form by a simple route, which is very important especially for an application in industrial processes from the point of view of costs.

In addition to the structure shown in formula II, however, the other isomeric forms of the dicarboxylic acids of the formula I (n=1) also have advantageous properties. Thus, in another embodiment, the dicarboxylic acids have a structure of the following formula III: 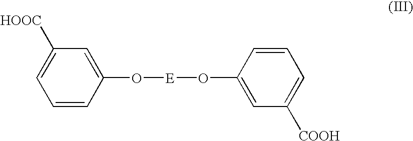
where E is as defined above in formula I.

In a further embodiment, the dicarboxylic acids have a structure of the following formula IV: 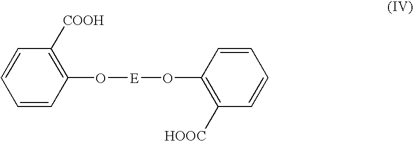
where E is as defined above in formula I.

The dicarboxylic acids of above formulas I-IV can be reacted with bis-o-aminophenols to give poly-o-hydroxyamides. To this end, the dicarboxylic acids of these formulas can be converted, for example, initially to an activated dicarboxylic acid derivative. It is suitable, for example, to convert the dicarboxylic acid to an acid chloride or an activated ester, for example a sulfonic ester. However, the reaction of the dicarboxylic acids with bis-o-aminophenols may also be carried out in the presence of a compound which activates the dicarboxylic acid, for example carbonyldiimidazole or dicyclohexylcarbodiimide. In principle, all reagents are suitable which bind the water formed in the reaction. For the preparation of the poly-o-hydroxyamides, the corresponding o-aminophenols and the dicarboxylic acids of any of the above formulas, or optionally activated derivatives thereof, are reacted in an organic solvent at from −20 to 150° C. within from 5 to 20 hours. If required, the end groups of the polymer may be capped with a suitable reagent. The poly-o-hydroxyamide formed after the reaction is precipitated in a precipitant by adding the reaction solution dropwise, washed and dried. Suitable precipitants are water, alcohols such as isopropanol, butanol or ethanol. It is also possible to use mixtures of these precipitants. It is also suitable for the precipitant to contain from 0.1 to 10% ammonia. The precipitated polymer may be further processed directly after filtration and drying and be dissolved, for example, in one of the solvents mentioned above for application to a semiconductor substrate.

The polymerization to the poly-o-hydroxyamide may be carried out in the presence of a base, in order to scavenge acid released. Suitable basic acid scavengers are, for example, pyridine, triethylamine, diazabicyclooctane, or polyvinylpyridine. It is also possible to use other basic acid scavengers. Special preference is given to compounds which have good solubility in the solvent used for the synthesis, for example N-methylpyrrolidone, and in the precipitant, for example water- or water-alcohol mixtures, or those which are completely insoluble in the solvent, for example crosslinked polyvinylpyridine. The acid scavengers can then be removed readily from the poly-o-hydroxyamide formed in the workup of the reaction product.

Particularly suitable solvents for the polymer synthesis are γ-butyrolactone, tetrahydrofuran, N-methylpyrrolidone and dimethylacetamide. However, it is possible per se to use any solvent in which the starting components have good solubility.

The dicarboxylic acids of formula I (and the other formulas) are readily obtainable, which is significant especially for an industrial application from the point of view of costs. The invention therefore also provides a process for preparing a dicarboxylic acid of formula I, by reacting a dihydroxyl compound of the following formula V:
HO—E—OH (V)
with a compound of the following formula VI: 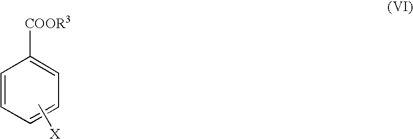
in which R³ is an alkyl or alkenyl group having from 1 to 10 carbon atoms or a benzyl group, X is a halogen atom and E is as defined above in formula I.

The halogen atom used in the compound of formula VI is preferably a fluorine atom. This yields dicarboxylic acids of formula I in which n is 1.

In the practical performance of the synthesis, the dihydroxyl compound of formula V is dissolved in from 4 to 10 times the amount of a suitable solvent based on the weight of the dihydroxyl compound. An example of a suitable solvent is N-methylpyrrolidone. Subsequently, the benzoic ester of the formula VI is added with stirring. Particular preference is given to using fluorobenzoic esters, especially 4-fluorobenzoic esters. The molar ratio of the dihydroxyl compound of formula V to the benzoic ester of formula VI is selected between 2 and 4 and is preferably 2.5. Subsequently, a base is added, for example potassium carbonate, and the reaction mixture is stirred under a protective gas atmosphere at elevated temperature up to complete conversion of the starting compound. The temperature is selected suitably within the range of 120-160° C., especially preferably within the region of 140° C. The reaction is complete generally within the time period of 14 to 20 hours, and the progress of the reaction can be monitored by suitable analytical methods, for example thin-layer chromatography. The base is used in about an equimolar amount relative to the benzoic ester of formula VI.

The benzoic esters of formula VI are preferably alkyl and alkenyl esters which include from 1 to 10 carbon atoms. Particularly suitable esters are ethyl esters, propyl esters, butyl esters and isopropyl esters. Additionally suitable are also the benzyl esters for the preparation of the dicarboxylic acids of formula I.

On completion of the reaction, the reaction solution is added dropwise to water with vigorous stirring. The opaque solution is left to stand until a precipitate has settled. The precipitate is subsequently removed by filtration and used for the next stage.

The precipitate is admixed with about 6 times the weight of aqueous 10% by weight potassium hydroxide solution and 10 times the weight of an alcohol, for example ethanol. The mixture is subsequently heated to boiling with stirring, in the course of which the precipitate dissolves. In general, from 4 to 8 times the weight of potassium hydroxide solution and from 7 to 15 times the amount of alcohol (ethanol) may be added. The reaction time is generally from 3 to 10 hours.

The reaction solution is subsequently concentrated under reduced pressure to from about half to one third of the original amount. The remaining solution is admixed with acid, for example concentrated hydrochloric acid, until it reacts acidically. The solution is subsequently extracted with a suitable organic solvent, for example ether, and the combined extracts are dried. The extractant may subsequently be evaporated under reduced pressure to isolate the dicarboxylic acid of formula I as a solid product. A further purification of the dicarboxylic acid may be achieved by recrystallization in a suitable solvent.

In most cases, polymers, for example the polybenzoxazole precursors, are prepared using the dicarbonyl chloride. The conversion of the dicarboxylic acid of formula I to the acid chloride may be carried out by known processes, for example with the aid of thionyl chloride.

The invention further relates to a process for preparing dicarboxylic acids of formula I, wherein an aromatic compound of the following formula VII:
H—E—H (VII)
where E is as defined above in formula I, is acetylated and the acetylated product is reacted with hypohalite under alkaline conditions to give the dicarboxylic acid of formula I.

In this process, the aromatic starting compound of formula VII is initially acetylated according to Friedel-Crafts, and the acetylated compound is subsequently converted to the corresponding carboxylic acid according to Einhorn.

In the practical performance of the synthesis, the aromatic compound of formula VII used as a starting compound is dissolved in about 30 times the amount of methylene chloride or another suitable solvent based on the weight of the starting compound. The solution is subsequently cooled to approx. −5° C. and admixed with pulverulent aluminum chloride. Equal molar amounts of aromatic starting compound and aluminum chloride are used. Subsequently, acetyl chloride is added, and about 10 times the molar amount is used based on the starting compound. The mixture is subsequently stirred at room temperature for from 6 to 24 hours. On completion of reaction, which can be monitored by suitable analytical methods such as thin-layer chromatography, the reaction solution is poured into ice-water and the resulting mixture is extracted repeatedly with methylene chloride or another suitable extractant. The combined extracts are washed with water and dried. The extractant is distilled off under reduced pressure, and the acetylated product remains.

To convert the acetyl compound to the acid, calcium hypochlorite is initially suspended in hot water. The water is used in about twice the weight relative to the calcium hypochlorite. This suspension is poured into a solution which consists of potassium carbonate, potassium hydroxide and water, and 4 times the weight of water based on the total weight of potassium carbonate and potassium hydroxide is used. The molar ratios of calcium hypochlorite, potassium carbonate and potassium hydroxide are about 1:8:5.

The acetyl compound prepared as described above is dissolved in about 12 times the weight of dioxane. This dioxane solution is added to the above-described solution of calcium hypochlorite, potassium carbonate and potassium hydroxide, and heated to boiling under reflux for one hour. The molar ratio of calcium hypochlorite to the acetyl compound is about 2:3.

After cooling to room temperature, the resulting mixture is admixed with, for example, methylene chloride as an extractant and water (in each case one third of the volume of the reaction solution). After the organic phase has been removed, the aqueous phase is acidified with hydrochloric acid to pH=1. This precipitates out the dicarboxylic acid of formula I. The precipitated dicarboxylic acid is removed by filtration, washed with water and dried. A further purification of the dicarboxylic acid can be achieved by recrystallization from a suitable solvent.

In the general description of the preparation of the dicarboxylic acids of formula I, certain solvents and bases were specified for the performance of the individual reaction steps, and also certain extractants for the extraction of the resulting products. However, it is immediately possible to replace these compounds by other solvents, bases and extractants which have comparable properties to the compounds mentioned.

The invention is illustrated in detail with reference to examples.

### EXAMPLE 1

### Synthesis of 9,9′-bis(4-(4-chlorocarbonyl)phenyloxy)phenylfluorene

Synthetic Route: 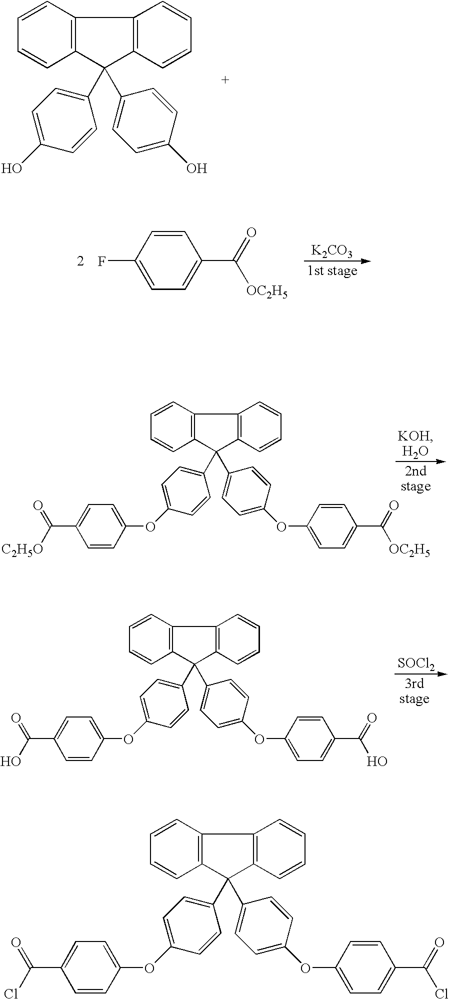
Stage 1: 9,9′-bis(4-(4-Ethoxycarbonylphenyl)oxyphenyl)fluorene

0.1 mol (35.04 g) of 9,9′-bis(4-hydroxyphenyl)fluorene is dissolved in 250 ml of NMP (N-methylpyrrolidone). 0.4 mol (67.27 g) of ethyl 4-fluorobenzoate is added with stirring. Subsequently, 0.4 mol (55.28 g) of potassium carbonate is introduced. The mixture is heated to 140° C. with stirring and under an N₂ protective gas atmosphere for another 24 hours. When the reaction has ended, the reaction solution is added dropwise to 3 liters of water with vigorous stirring. Afterward, the whitish, cloudy solution is left to stand for from 1 to 2 hours, so that the precipitate can settle. The supernatant milky-white solution above the precipitate is decanted off and the remaining precipitate is filtered with suction.

Yield: 54.93 g (85% of theory)

Stage 2: 9,9′-bis(4-(4-Hydroxycarbonylphenyl)oxyphenyl)fluorene

51.7 g (0.08 mol) of 9′9′-bis(4-(4-ethoxycarbonylphenyl)oxyphenyl)fluorene are admixed with 300 ml of water in which 30 g of KOH have been dissolved before-hand, and 500 ml of ethanol. Subsequently, the mixture is heated to boiling under reflux with stirring for 6 hours, in the course of which the solid dissolves slowly. The ethanol is distilled off under reduced pressure and the remaining aqueous solution is acidified strongly with conc. HCl (pH=1). The mixture is extracted three times with ether and the combined extracts are dried over sodium sulfate. The sodium sulfate is removed by filtration and the ether is subsequently distilled off under reduced pressure.

Yield: 42.02 g (89% of theory)

Stage 3: 9,9′-bis(4-(4-Chlorocarbonyl)phenyloxy)phenylfluorene

29.51 g (0.05 mol) of 9,9′-bis(4-(4-hydroxycarbonylphenyl)oxyphenyl)fluorene are heated to boiling under reflux in 300 ml of thionyl chloride with stirring and under an N₂ protective gas atmosphere, until the evolution of gas is complete. The thionyl chloride is distilled off under reduced pressure and the resulting residue is recrystallized from toluene.

Yield: 25.36 g (81% of theory)

### EXAMPLE 2

### Synthesis of 4,4′-di(4-(chlorocarbonyl)phenyloxy)tetraphenylmethane

Synthetic Route: 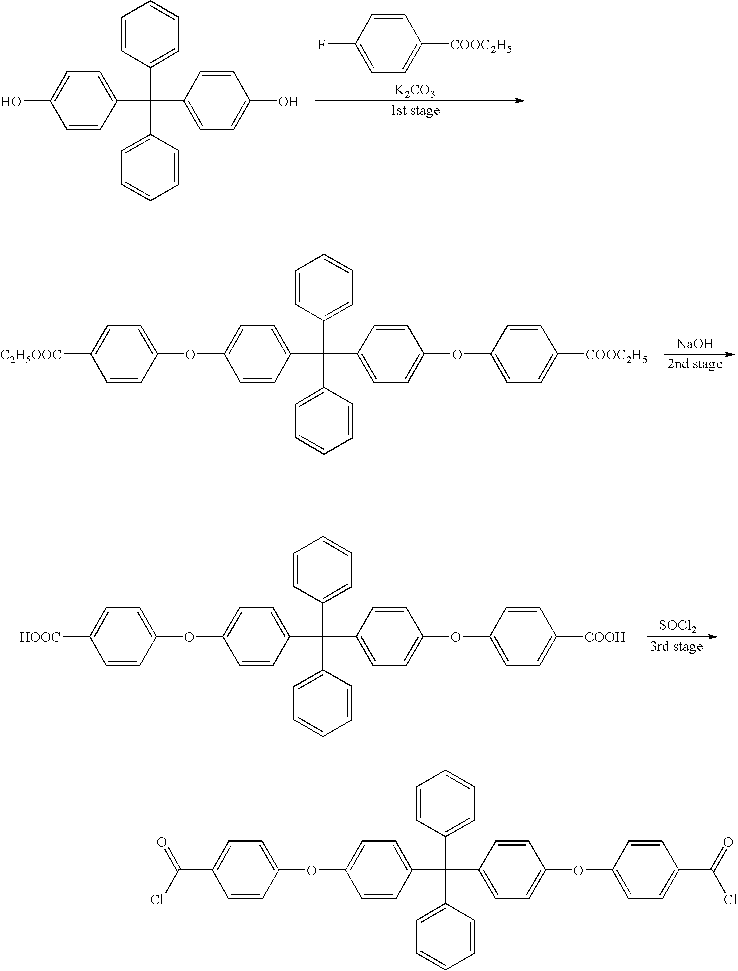
Stage 1: 4,4′-Di((4-ethoxycarbonylphenyl)oxy)tetraphenylmethane

Procedure is similar to Example 1 stage 1.

Stage 2: 4,4′-Di((4-hydroxycarbonylphenyl)oxy)tetraphenylmethane

Procedure is similar to Example 1 stage 2.

Stage 3: 4,4′-Di(4-(chlorocarbonyl)phenyloxy)tetraphenylmethane

Procedure is similar to Example 1 stage 3.

### EXAMPLE 3

### Synthesis of 2,2′-di(4-chlorocarbonyl)phenyloxy)-1,1′-binaphthyl

Synthetic Route: 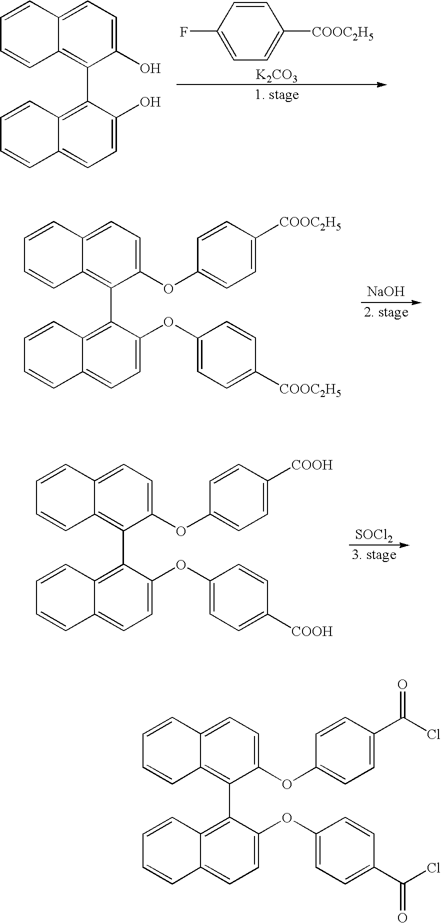
Stage 1: 2,2′-Di((4-ethoxycarbonylphenyl)oxy)-1,1′-binaphthyl

Procedure is similar to Example 1 stage 1.

Stage 2: 2,2′-Di((4-hydroxycarbonylphenyl)oxy)-1,1′-binaphthyl

Procedure is similar to Example 1 stage 2.

Stage 3: 2,2′-Di(4-(chlorocarbonyl)phenyloxy)-1,1′-binaphthyl

Procedure is similar to Example 1 stage 3.

### EXAMPLE 4

### Synthesis of 2,7-di-tert-butylpyrene-4,9-dicarbonylchloride

Synthetic Route: 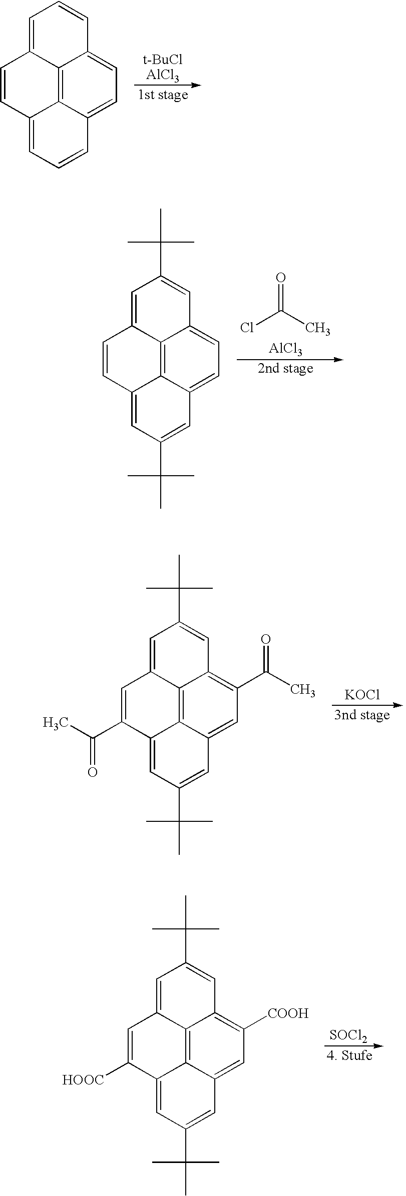 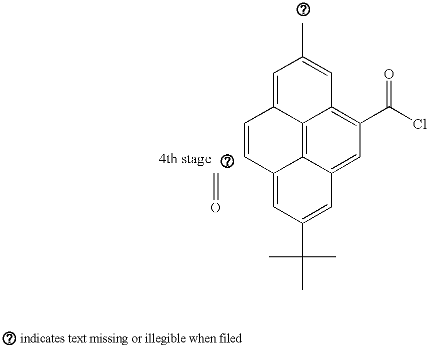
Stage 1: 2,7-Di-tert-butylpyrene

8 g (0.06 mol) of aluminum chloride powder are introduced at 0° C. into a solution of 8 g (0.04 mol) of pyrene in 200 ml of tert-butyl chloride. Subsequently, the mixture is stirred at room temperature for another 3 hours. The reaction mixture is introduced slowly into 1.5 liters of ice-water with stirring and extracted twice with 250 ml each time of methylene chloride. The combined organic phases are washed twice with 200 ml each time of water and dried over sodium sulfate, and the solvent is distilled off under reduced pressure. The residue is recrystallized from ethanol.

Yield: 10 g (85% of theory)

Stage 2: 4,9-Diacetyl-2,7-di-tert-butylpyrene

10.1 g (0.075 mol) of aluminum chloride powder are introduced at −15° C. with stirring into a solution of 10 g (0.032 mol) of 2,7-di-tert-butylpyrene in 300 ml of methylene chloride, and 25 g (0.32 mol) of acetyl chloride are subsequently added dropwise. The mixture is warmed slowly to room temperature and stirred for a further 12 hours. The reaction mixture is introduced slowly with stirring into 1.5 liters of ice-water and extracted twice with 250 ml each time of methylene chloride. The combined organic phases are washed twice with 200 ml of water and dried over sodium sulfate, and the solvent is distilled off under reduced pressure. The residue is recrystallized from acetic anhydride.

Yield: 9.5 g (57% of theory)

Stage 3: 2,7-Di-tert-butylpyrene-4,9-dicarboxylic Acid

A solution of 13 g (0.094 mol) of potassium carbonate and 3.7 g (0.066 mol) of KOH in 60 ml of water are added to a solution of 18 g (0.0125 mol) of calcium hypochlorite into 25 ml of hot water. A solution of 7 g (0.018 mol) of 4,9-diacetyl-2,7-di-tert-butylpyrene in 90 ml of dioxane is added to the solution. The mixture is heated to boiling under reflux with stirring for 1 hour. 50 ml of water are added to the reaction mixture and the mixture is washed with 50 ml of chloroform. The aqueous phase is acidified to pH=1 with conc. HCl. The precipitated solid is filtered off with suction to a frit, washed with water and dried under reduced pressure.

Yield: 5.1 g (72% of theory)

Stage 4: 2,7-Di-tert-butylpyrene-4,9-dicarbonyl Chloride

Procedure is similar to Example 1 stage 3.

### EXAMPLE 5

### Synthesis of 9,10-bis(4-chlorocarbonylphenyl)anthracene

Synthetic Route: 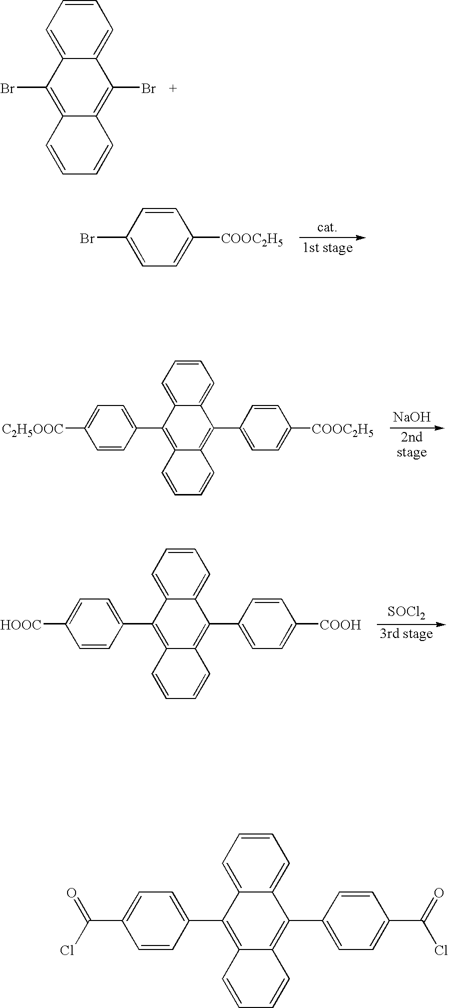
Stage 1: 9,10-bis(4-Ethoxycarbonylphenyl)anthracene

3.34 g (0.01 mol) of 9,10-dibromoanthracene and 0.2 g of tetrakis(triphenylphosphine)nickel(0) are dissolved in 200 ml of dry tetrahydrofuran (THF). 6.83 g (0.03 mol) of ethyl 4-bromobenzoate dissolved in 100 ml of dry THF are added dropwise with stirring to the solution. The mixture is heated to boiling under reflux with stirring for a further 12 hours. The reaction solution is filtered and the THF is distilled off under reduced pressure. The residue is recrystallized from toluene.

Yield: 2.6 g (56% of theory)

Stage 2: 9,10-bis(4-Hydroxycarbonylphenyl)anthracene

The procedure is similar to Example 1 stage 2.

Stage 3: 9,10-bis(4-Chlorocarbonylphenyl)anthracene

The procedure is similar to Example 1 stage 3.

While the invention has been described in detail and with reference to specific embodiments thereof, variations and changes will be suggested to those skilled in the art in view of the teachings set forth herein. It is therefore to be understood that all such variations, modifications and changes are believed to fall within the scope of the present invention as defined by the appended claims.

1. A dicarboxylic acid of the following formula I for use in producing dielectrics having barrier action against copper diffusion: 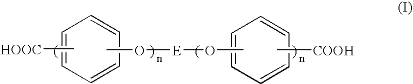
where:
E is any of the following: 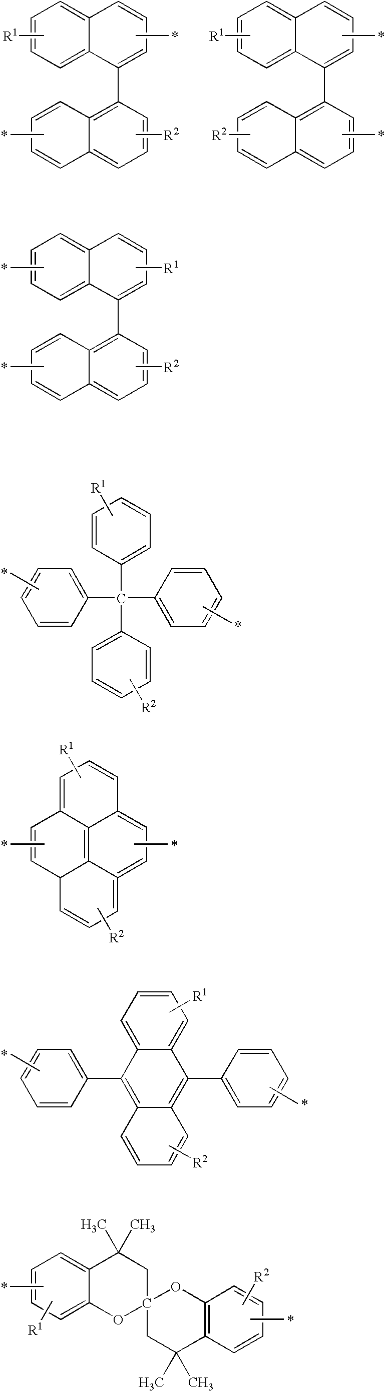 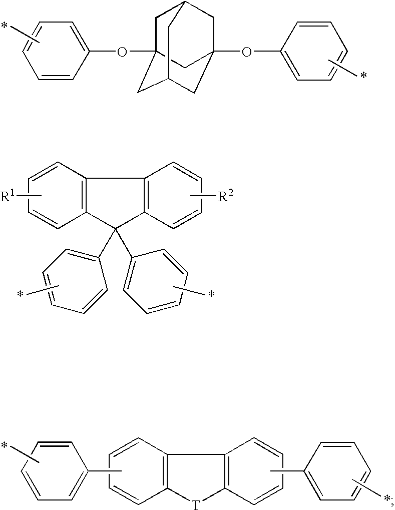
T is any of the following: 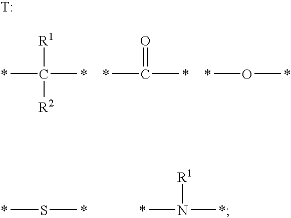
R¹, R² are independent of each other and each of R¹ and R²is any of the following: 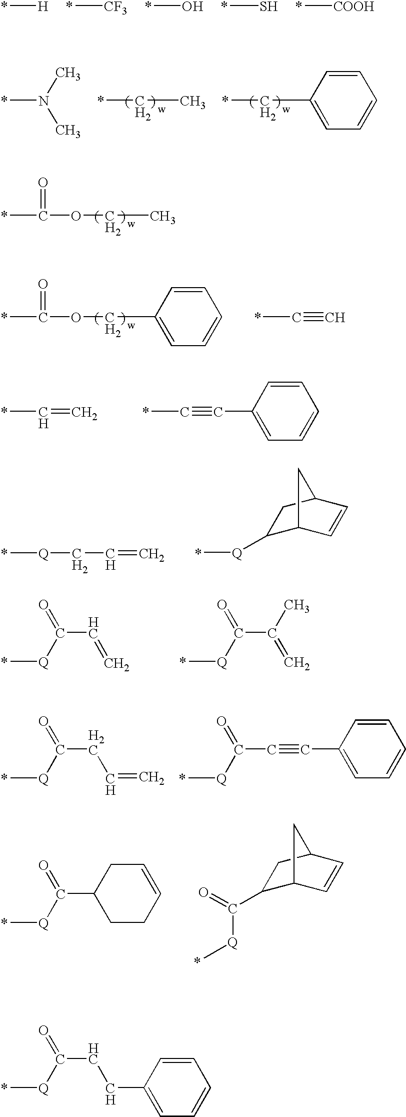
Q is independent for each of R¹ and R² and is any of the following: 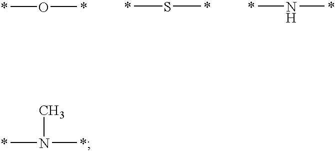
n is 0 or 1; and
w is an integer from 0 to 10.

2. The dicarboxylic acid of claim 1, wherein n=1.

3. The dicarboxylic acid of claim 1, wherein the dicarboxylic acid is further of the following formula II: 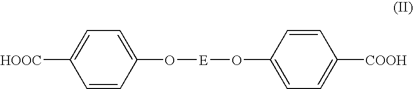
wherein E is as defined in formula I.

4. The dicarboxylic acid of claim 1, wherein the dicarboxylic acid is further of the following formula III: 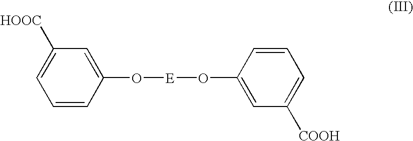
wherein E is as defined in formula 1.

5. The dicarboxylic acid of claim 1, wherein the dicarboxylic acid is further of the following formula IV: 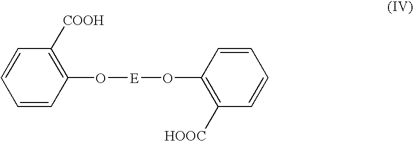
wherein E is as defined in formula 1.

6. A process for preparing a dicarboxylic acid of claim 1, comprising:
reacting a dihydroxyl compound of the following formula V:
HO—E—OH (V)
with a compound of the following formula VI: 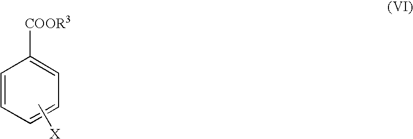
wherein E is as defined in formula I, R³ is an alkyl or alkenyl group having from 1 to 10 carbon atoms or a benzyl group and X is a halogen atom.

7. A process for preparing a dicarboxylic acid of claim 1, comprising:
acetylating an aromatic compound of the following formula VII to form an acetylated product:
H—E—H (VII)
wherein E is as defined in formula I; and
reacting the acetylated product with hypohalite under alkali conditions to yield a dicarboxylic acid of the formula I.
